(19) United States
(12) Patent Application Publication
(10) Pub. No.: US 2024/0087940 A1
(43) Pub. Date: Mar. 14, 2024

(54) WAFER TEMPORARY ADHESIVE TAPE, WAFER STACK STRUCTURE, AND METHOD OF PROCESSING SEMICONDUCTOR WAFER BY USING THE WAFER TEMPORARY ADHESIVE TAPE

(71) Applicant: SAMSUNG ELECTRONICS CO., LTD., Suwon-si (KR)

(72) Inventors: Cheonil PARK, Suwon-si (KR); Myoungchul EUM, Suwon-si (KR)

(21) Appl. No.: 18/243,725

(22) Filed: Sep. 8, 2023

(30) Foreign Application Priority Data
Sep. 8, 2022 (KR) 10-2022-0114465

(51) Int. Cl. H01L 21/683; C09J 7/29; C09J 7/38

(52) U.S. Cl. CPC H01L 21/6836; C09J 7/29; C09J 7/385; C09J 2203/326; C09J 2301/416; C09J 2433/00; H01L 2221/68327; H01L 2221/68386

(57) ABSTRACT

A wafer temporary adhesive tape includes a device adhesive layer configured to be attached to a device wafer, a base layer on the device adhesive layer, and a carrier adhesive layer on the base layer and configured to be attached to a carrier wafer, wherein the base layer includes a laser decomposable material layer that can be chemically decomposed by absorbing a laser beam.

### CROSS-REFERENCE TO RELATED APPLICATION

This application is based on and claims priority under 35 U.S.C. § 119 to Korean Patent Application No. 10-2022-0114465, filed on Sep. 8, 2022, in the Korean Intellectual Property Office, the disclosure of which is incorporated by reference herein in its entirety.

### BACKGROUND

### 1. Field

Embodiments relate to a wafer temporary adhesive tape, a wafer stack structure, and a method of processing a semiconductor wafer by using the wafer temporary adhesive tape. More particularly, embodiments relate to a wafer temporary adhesive tape that may enable a carrier wafer to be attached (for example, bonded) to a device wafer or to be detached (for example, de-bonded) from a device wafer or a wafer stack structure. Embodiments further relate to a method of processing a semiconductor wafer by using the wafer temporary adhesive tape.

### 2. Description of the Related Art

Semiconductor wafers may be manufactured to be device wafers using a plurality of wafer processes. Thicknesses of semiconductor packages may be reduced only when a thickness of device wafers is in a range tens of um (for example, about 50 um to about 100 um). Accordingly, a wafer process to decrease a thickness of semiconductor wafers (for example, by a wafer polishing (grinding) process) is desired.

Furthermore, because a diameter of device wafers (or semiconductor wafers) is hundreds mm (for example, about 300 mm (12 inch) or about 450 mm (18 inch)) and is large, carrier wafers (or carrier substrates) for transporting or handling a device wafer having a thin thickness and a large diameter in processing a wafer are desired. Because carrier wafers are used while being adhered to device wafers, wafer temporary adhesive tapes for attaching (bonding) or detaching (de-bonding) a carrier wafer to or from a device wafer are desired.

### SUMMARY

Embodiments are directed to wafer temporary adhesive tape including a device adhesive layer configured to be attachable to a device wafer, a base layer on the device adhesive layer, and a carrier adhesive layer on the base layer and configured to be attachable to a carrier wafer, wherein the base layer includes a laser decomposable material layer chemically decomposed by absorbing a laser beam.

Embodiments are further directed to a wafer stack structure including, a device wafer, a carrier wafer configured to support the device wafer, and a wafer temporary adhesive tape between the device wafer and the carrier wafer, wherein the wafer temporary adhesive tape includes a device adhesive layer attached on the device wafer, a base layer on the device adhesive layer, and a carrier adhesive layer attached to the carrier wafer, on the base layer, wherein the base layer includes a laser decomposable material layer chemically decomposed by absorbing a laser beam

Embodiments are further directed to a method of processing a semiconductor wafer, the method including attaching a wafer temporary adhesive tape, which includes a device adhesive layer, a base layer, and a carrier adhesive layer, to a device wafer, attaching a carrier wafer to the carrier adhesive layer, primarily irradiating a laser beam to cure the carrier adhesive layer and the device adhesive layer, processing the device wafer, secondarily irradiating a laser beam to chemically decompose the base layer, detaching the base layer from the carrier adhesive layer to detach the carrier wafer from the device wafer, and detaching the device adhesive layer and the base layer from the device wafer.

### BRIEF DESCRIPTION OF THE DRAWINGS

Features will become apparent to those of skill in the art by describing in detail exemplary embodiments with reference to the attached drawings in which:

FIG. 1 is a cross-sectional view for describing a wafer temporary adhesive tape according to an embodiment;

FIGS. 2A and 2B are cross-sectional view for describing a wafer stack structure using a wafer temporary adhesive tape, according to an embodiment;

FIGS. 3 to 6 are cross-sectional view for describing a method of forming a wafer stack structure, according to an embodiment;

FIGS. 7 to 11 are cross-sectional view for describing a method of processing a wafer by using a wafer stack structure, according to an embodiment;

FIG. 12 is a diagram illustrating an absorbance of a base layer of a wafer temporary adhesive tape, according to an embodiment;

FIG. 13 is a flowchart for describing an embodiment of a method of processing a semiconductor wafer by using a wafer temporary adhesive tape according an embodiment;

FIG. 14 is a cross-sectional view for describing a semiconductor chip manufactured by a method of processing a semiconductor wafer, according to an embodiment;

FIG. 15 is a cross-sectional view for describing a semiconductor chip manufactured by a method of processing a semiconductor wafer, according to an embodiment;

FIG. 16 is a cross-sectional view illustrating a semiconductor package including a semiconductor chip manufactured by a method of processing a semiconductor wafer, according to an embodiment; and

FIGS. 17 and 18 are diagrams illustrating a semiconductor package including a semiconductor chip manufactured by a method of processing a semiconductor wafer, according to an embodiment.

### DETAILED DESCRIPTION

Example embodiments will now be described more fully hereinafter with reference to the accompanying drawings. However, they may be embodied in different forms and should not be construed as limited to the embodiments set forth herein.

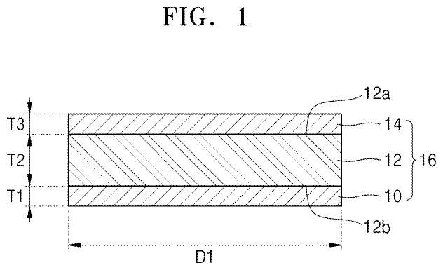

FIG. 1 is a cross-sectional view for describing a wafer temporary adhesive tape 16 according to an embodiment. In detail, FIG. 1 is a cross-sectional view of the wafer temporary adhesive tape 16. The wafer temporary adhesive tape 16 may include a device adhesive layer 10, a base layer 12, and a carrier adhesive layer 14.

The device adhesive layer 10, as described in more detail below, may be adhered to a device wafer. The carrier adhesive layer 14, as described below, may be adhered to a carrier wafer. The base layer 12 may be a substance layer or a supporting layer that physically supports the device adhesive layer 10 and the carrier adhesive layer 14. The base layer 12 may include a front surface 12a and a rear surface 12b.

The wafer temporary adhesive tape 16 may have a diameter D1. The diameter D1 may be about equal to that of the below-described device wafer or carrier wafer. The diameter D1 may correspond to a diameter (for example, about 300 mm (12 inch) or about 450 mm (18 inch)) of the device wafer or the carrier wafer.

Herein, each of elements configuring the wafer temporary adhesive tape 16 will be described in more detail.

The device adhesive layer 10 may be referred to as a device adhesive film. In the following description, the term “adhesive” may be a comprehensive term including all types of viscosity and adhesiveness. There may be a difference between viscosity and adhesiveness in strict meaning, but the term “adhesive” described herein may encompass all types of adhesive and bonds in English. Also, in the following description, the term “attachment” may encompass the term “viscosity” and “adhesiveness”.

In some embodiments, the device layer 10 may include an acrylic polymer, a cross linker, an additive, and a photo initiator. The acrylic polymer may include metaacrylate or alkyl acrylate having four to seventeen carbon atoms of a monomer composition alkyl group. The acrylic polymer may include about 50% to about 90% of a monomer such as 2-ethylhexyl acrylate (2-EA), about 10% to about 40% of a monomer such as meta acrylate, vinyl acetate (VAc), or styrene (ST) provided as an agglutination component, and about 2% to about 20% of a monomer such as acrylic acid (AA) or methyl methacrylic acid (MMA) provided as a functional component.

The cross linker may use any materials having isocyanate without being limited. For example, the cross linker may include one or more kinds of materials selected from cycloaliphatic compounds such as isophorone diisocyanate and methylenebiscyclohexane diisocyanate, aliphatic compounds such as hexamethylene diisocyanate, and aromatic compounds such as toluene diisocyanate (TDI), methylenediphenyl diisocyanate (MDI), and m-tetramethylxylylene diisocyanate (TMXDI).

The additive may include a material for enhancing a modulus. In some embodiments, the additive may use silica.

In some embodiments, the photo initiator may include a material for inducing photo-curing under a condition where a wavelength of a laser beam is more than about 350 nm and about 650 nm or less. In some embodiments, the photo initiator may include one or more kinds of materials selected from a benzoin compound, an acetophenone compound, an acyl phosphine oxide compound, a titanocene compound, a thioxanthone compound, amine, and quinone. For example, the photo initiator may include 1-hydroxycyclohexyl phenyl ketone, benzoin, benzoin methyl ether, benzoin ethyl ether, benzoin isopropyl ether, benzyl diphenyl sulfide, tetramethylthiuram monosulfide, azobisisobutyronitrile, dibenzyl, diacetyl, and β-chloroanthraquinone, as non-limiting examples.

The materials included in the device adhesive layer 10 are not limited to the materials described above. The device adhesive layer 10 may have a first thickness T1. In some embodiments, the first thickness T1 may be about 1 um to about 200 um.

The base layer 12 may be disposed on the device adhesive layer 10. The device adhesive layer 10 may be attached on the rear surface 12b of the base layer 12. The base layer 12 may be referred to as a base film. The base layer 12 may include a laser decomposable material layer which may be chemically decomposed by absorbing a laser beam.

The base layer 12 may include a material which absorbs a laser beam under a condition where a wavelength of a laser beam is about 200 nm to about 350 nm. In some embodiments, the base layer 12 may have a laser beam absorbance of 15% or more under a condition where a wavelength of a laser beam is about 200 nm to about 350 nm. In some embodiments, the base layer 12 may have a laser beam absorbance of 100% under a condition where a wavelength of a laser beam is about 300 nm. In some embodiments, the base layer 12 may have a laser beam absorbance of less than 15% under a condition where a wavelength of a laser beam is more than about 350 nm and about 650 nm or less.

In some embodiments, the base layer 12 may include a polymer layer. In some embodiments, the base layer 12 may include polyethyleneterephthalate (PET), polyethylenenaphthalate (PEN), polyetheretherketone (PEEK), polyimide (PI), or polybenzoxazoles (PBO).

The base layer 12 is not limited to the materials described above. The base layer 12 may have a second thickness T2. The second thickness T2 of the base layer 12 may be thicker than the first thickness T1 of the device adhesive layer 10. In some embodiments, the second thickness T2 may be about 1 um to about 200 um. In some embodiments, unlike what is shown in FIG. 1, the second thickness T2 of the base layer 12 may be the same as the first thickness T1 of the device adhesive layer 10.

The carrier adhesive layer 14 may be disposed on the base layer 12. The carrier adhesive layer 14 may be attached on the surface 12a of the base layer 12. In some embodiments, the carrier adhesive layer 14 may include the same material as that of the device adhesive layer 10 described above. In other words, the carrier adhesive layer 14 may include an acrylic polymer, a cross linker, an additive, and a photo initiator. In some embodiments, the photo initiator included in the carrier adhesive layer 14 may include a material for inducing photo-curing under a condition where a wavelength of a laser beam is more than about 350 nm and about 650 nm or less.

The carrier adhesive layer 14 may have a third thickness T3. In some embodiments, the third thickness T3 of the carrier adhesive layer 14 may be the same as the first thickness T1 of the device adhesive layer 10. In some embodiments, the third thickness T3 of the carrier adhesive layer 14 may be less than the second thickness T2 of the base layer 12.

In some embodiments, unlike what is shown in FIG. 1, the third thickness T3 of the carrier adhesive layer 14 may be the same as the second thickness T2 of the base layer 12. In some embodiments, the third thickness T3 may be about 1 um to about 200 um. Accordingly, a total thickness of the wafer temporary adhesive tape 16 may be about 3 um to about 600 um.

As described above, the wafer temporary adhesive tape 16 may include the device adhesive layer 10, the base layer 12, and the carrier adhesive layer 14. The wafer temporary adhesive tape 16 may include the base layer 12, which may be chemically decomposed by absorbing a laser beam.

Therefore, as described below, the wafer temporary adhesive tape 16 according to an embodiment may be easily detached (de-bonded) from a device wafer that has been processed by using a laser beam. Furthermore, the device adhesive layer 10 and the base layer 12 that are each disposed on a device wafer may be physically and easily detached (de-bonded).

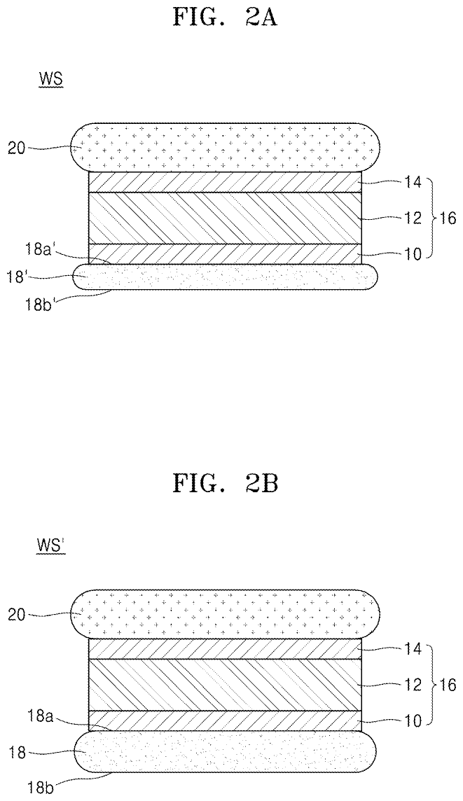

FIGS. 2A and 2B are cross-sectional view for describing a wafer stack structure using a wafer temporary adhesive tape, according to an embodiment.

In detail, as illustrated in FIG. 2A, a wafer stack structure WS may include a device wafer 18′, a carrier wafer 20 supporting the device wafer 18′, and a wafer temporary adhesive tape 16 formed between the device wafer 18′ and the carrier wafer 20. The device wafer 18′ may include a surface 18a′ and a rear surface 18b′. The surface 18′ may be a surface where active devices are formed.

As illustrated in FIG. 2B, a wafer stack structure WS′ may include a device wafer 18, a carrier wafer 20 supporting the device wafer 18, and a wafer temporary adhesive tape 16 formed between the device wafer 18 and the carrier wafer 20. The device wafer 18 may include a surface 18a and a rear surface 18b. The surface 18a may be a surface where active devices are formed.

The device wafer 18′ of the wafer stack structure WS of FIG. 2A may be thinner than the device wafer 18 of the wafer stack structure WS′ of FIG. 2B. The device wafer 18′ of the wafer stack structure WS of FIG. 2A may be obtained by processing the device wafer 18 of the wafer stack structure WS′ of FIG. 2B (for example, by grinding a rear surface of the device wafer 18).

The carrier wafer 20 may include a glass material or a transparent acryl material. The device wafer 18 (18′) may include a semiconductor material (for example, silicon). The device wafer 18 (18′) may include a plurality of chips. Each of the plurality of chips may include an individual device. Each individual device may include various microelectronics devices. For example, a microelectronic device may include a metal-oxide-semiconductor field effect transistor (MOSFET) such as a complementary metal-insulator-semiconductor (CMOS) transistor, an image sensor such as system large scale integration (LSI) a CMOS imaging sensor (CIS), a micro-electro-mechanical system (MEMS), an active device, or a passive device.

In some embodiments, each chip may include a logic chip, a power management integrated circuit (PMIC) chip, or a memory chip. In some embodiments, the logic chip may include a memory controller chip, a central processing unit (CPU) chip, a graphics processing unit (GPU) chip, or an application processor (AP) chip.

In some embodiments, the logic chip may include a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The wafer temporary adhesive tape 16 may be a tape that temporarily attaches the device wafer 18 to the carrier wafer 20. A configuration of the wafer temporary adhesive tape 16 has been described above, and thus, a description thereof will not be repeated.

Hereinafter, a method of forming a wafer stack structure by using the wafer temporary adhesive tape 16 described above will be described.

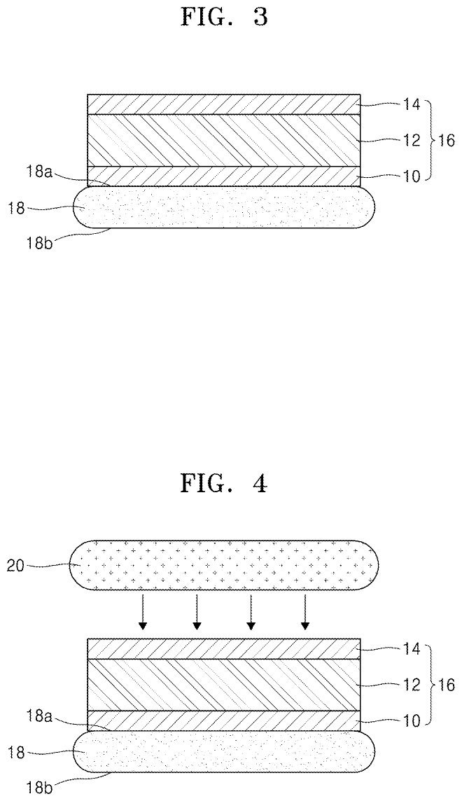

FIGS. 3 to 6 are cross-sectional views for describing a method of forming a wafer stack structure according to an embodiment.

Referring to FIG. 3, a wafer temporary adhesive tape 16 may be adhered (bonded) to a device wafer 18. The wafer temporary adhesive tape 16 may include a device adhesive layer 10, a base layer 12, and a carrier adhesive layer 14. A configuration of the wafer temporary adhesive tape 16 has been described above, and thus, a description thereof will not be repeated. The device wafer 18 may include a surface 18a and a rear surface 18b. The surface 18a may be a surface where active devices are formed.

The wafer temporary adhesive tape 16 may be adhered to the surface 18a of the device wafer 18. The device adhesive layer 10 of the wafer temporary adhesive tape 16 may be adhered to the surface 18a of the device wafer 18. The wafer temporary adhesive tape 16 may be adhered to the surface 18a of the device wafer 18 so as to protect the surface 18a of the device wafer 18 in processing a wafer. The wafer temporary adhesive tape 16 may have a diameter of the device wafer 18, and for example, the wafer temporary adhesive tape may have a diameter of about 300 mm (12 inch) to about 450 mm (18 inch).

Referring to FIG. 4, a carrier wafer 20 may be adhered (bonded) to the wafer temporary adhesive tape 16. The carrier wafer 20 may be adhered to the carrier adhesive layer 14 of the wafer temporary adhesive tape 16.

The carrier wafer 20 may support the device wafer 18 in processing the device wafer 18. The carrier wafer 20 may support the device wafer 18 in transporting or handling the device wafer 18. The carrier wafer 20 may have a diameter of the device wafer 18, which may be, for example, a size of about 300 mm (12 inch) to about 450 mm (18 inch).

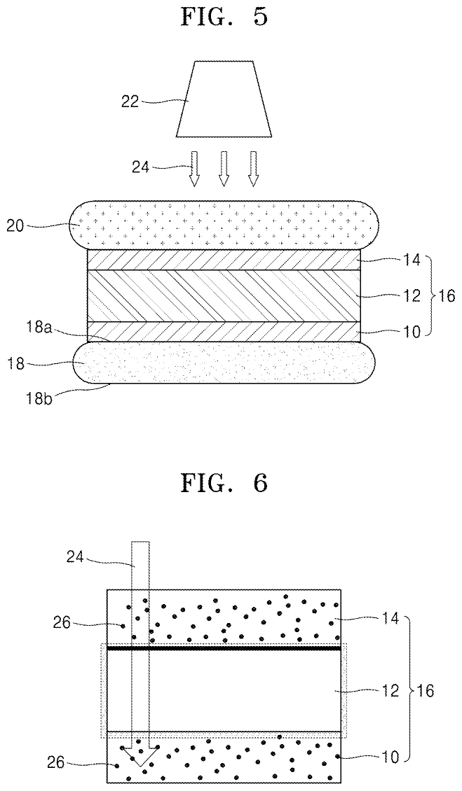

Referring to FIGS. 5 and 6, it is illustrated in FIG. 5 that the wafer temporary adhesive tape 16 and the carrier wafer 20 are stacked on the device wafer 18. In FIG. 5, it is illustrated that the device wafer 18 is adhered to the carrier wafer 20 by the wafer temporary adhesive tape 16.

As illustrated in FIG. 5, in order to enhance the adhesive performance between the device wafer 18 and the carrier wafer 20, a primary laser beam 24 may be applied to the stacked structure of the device wafer 18, the wafer temporary adhesive tape 16, and the carrier wafer 20. The primary laser beam 24 may be applied from a laser source 22. In some embodiments, unlike what is depicted in FIG. 5, the primary laser beam 24 may not be applied.

As described above, the primary laser beam 24 may be applied for curing the device adhesive layer 10 and the carrier adhesive layer 14. The primary laser beam 24 may pass through the device adhesive layer 10, the base layer 12, and the carrier adhesive layer 14.

The primary laser beam 24 may have a wavelength that allows a photo initiator 26 included in the device adhesive layer 10 and the carrier adhesive layer 14 to induce photo-curing. In some embodiments, the primary laser beam 24 may have a wavelength of more than about 350 nm to about 650 nm or less. Under a condition where a wavelength of the primary laser beam 24 is more than about 350 nm and about 650 nm or less, less than 15% of the primary laser beam 24 may be absorbed by the base layer 12.

The device adhesive layer 10 and the carrier adhesive layer 14 may adhere better to the wafer temporary adhesive tape 16, based on the amount of photo-curing of the device adhesive layer 10 and the carrier adhesive layer 14. Through such a process, a wafer stack structure (WS′ of FIG. 2B) may be manufactured.

Hereinafter, a wafer processing method using the wafer stack structure WS′ described above will be explained.

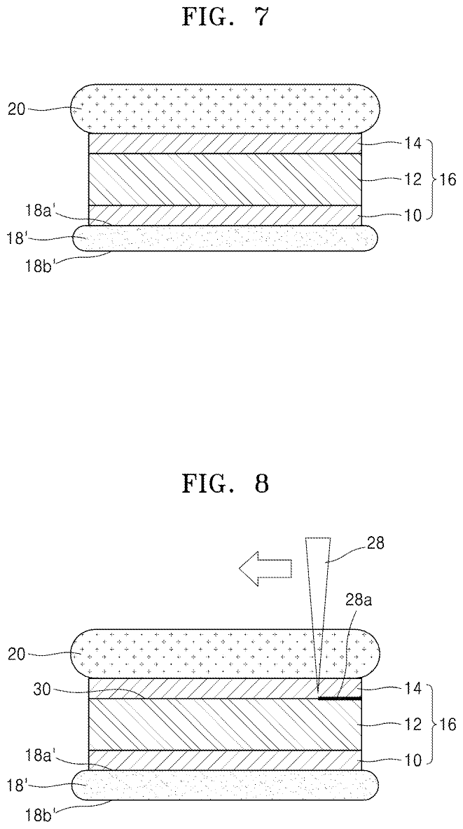

FIGS. 7 to 11 are cross-sectional view for describing a method of processing a wafer by using a wafer stack structure, according to an embodiment.

Referring to FIG. 7, a process of processing a device wafer (18 of FIG. 5) may be performed. For example, a process of polishing a rear surface 18b of the device wafer (18 of FIG. 5) to decrease a thickness of the device wafer (18 of FIG. 5) may be performed. Therefore, the device wafer (18 of FIG. 5) may be changed to be a device wafer 18′ where a thickness thereof has been reduced. The device wafer 18′ may include a surface 18a′ and a rear surface 18b′.

In an embodiment, a wafer polishing process has been described as an example of a wafer processing process. In some implementations, the wafer processing process may include a process of forming a wiring provided on the rear surface 18b′ of the device wafer 18′ or a process of forming a bump. The wafer processing process is not limited to the above description.

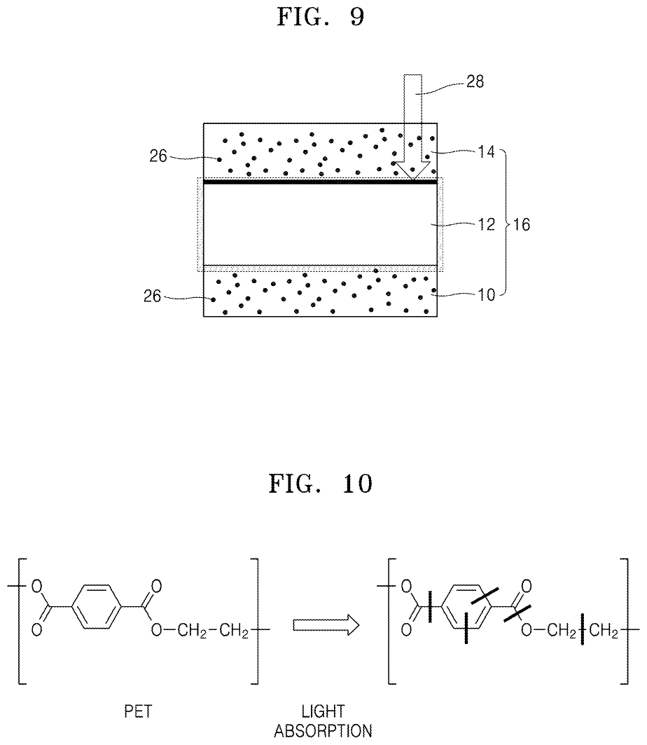

Referring to FIGS. 8 to 10, as illustrated in FIGS. 8 and 9, in order to detach (de-bond) the carrier wafer 20 from the device wafer 18′, a secondary laser beam 28 may be applied to a structure where the device wafer 18′, the wafer temporary adhesive tape 16, and the carrier wafer 20 are stacked. The secondary laser beam 28 may be applied from the laser source (22 of FIG. 5) described above.

As illustrated in FIGS. 8 and 9, the secondary laser beam 28 may be applied to an interface 30 between the base layer 12 and the carrier adhesive layer 14. In FIG. 8, a reference number 28a refers to a secondary laser beam that is applied to the interface 30 between the base layer 12 and the carrier adhesive layer 14. The secondary laser beam 28 may pass through the carrier wafer 20 and the carrier adhesive layer 14. The secondary laser beam 28 may not pass through the base layer 12, but instead may be absorbed by the base layer 12.

The secondary laser beam 28 may have a wavelength that can be absorbed by the base layer 12 and that can chemically decompose the base layer 12. In some embodiments, the secondary laser beam 28 may have a wavelength of about 200 nm to about 350 nm. More than 10% of the secondary laser beam 28 may be absorbed by the base layer 12 under a condition where a wavelength thereof is about 200 nm to about 350 nm. About 100% of the secondary laser beam 28 may be absorbed by the base layer 12 under a condition where a wavelength thereof is about 300 nm.

As described above, the base layer 12 may include PET, PEN, PEEK, PI, or PBO.

In FIG. 10, a chemical structure of PET among the materials is illustrated. As illustrated in FIG. 10, when the secondary laser beam 28 is applied to PET included in the base layer 12, a chemical bond constituting PET may be broken, and thus, PET may evaporate in a gas form. The material that evaporates in a gas form may be CO, CO₂, C₂H₄, or O₂.

Through such a process, the carrier adhesive layer 14 and the carrier wafer 20 may be detached (de-bonded) from the base layer 12. The interface 30 between the carrier adhesive layer 14 and the base layer 12 may be chemically detached by the secondary laser beam 28 of the base layer 12. As a result, the carrier adhesive layer 14 and the carrier wafer 20 may be chemically detached (de-bonded) from the device wafer 18′.

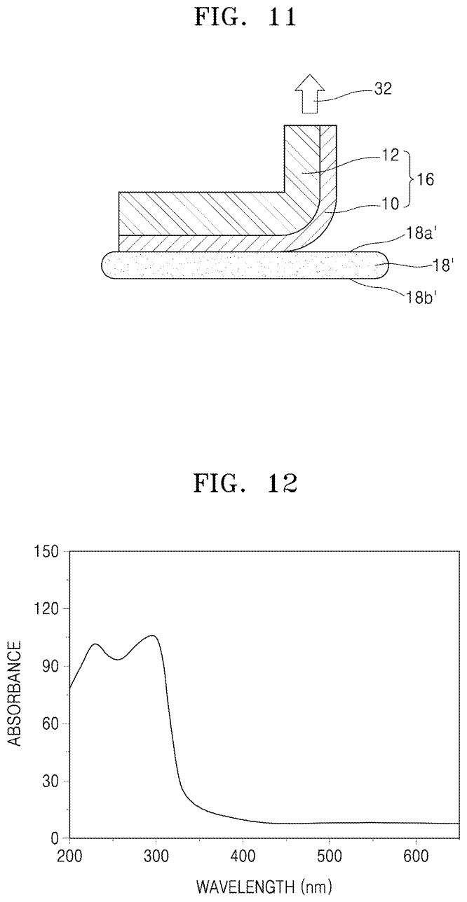

Referring to FIG. 11, after the carrier adhesive layer 14 and the carrier wafer 20 are chemically detached (de-bonded) from the device wafer 18′, the device adhesive layer 10 and the base layer 12 may be physically detached (de-bonded) from the device wafer 18′, as illustrated in FIG. 11.

The physical detaching (de-bonding) of the device adhesive layer 10 and the base layer 12 may be a peel-off process performed by controlling an adhesive force between a surface 18a′ of the device wafer 18′ and a rear surface of the device adhesive layer 10 using a physical force 32. Through such a process, the device adhesive layer 10 and the base layer 12 may be removed from the device wafer 18′.

FIG. 12 is a diagram illustrating an absorbance of a base layer of a wafer temporary adhesive tape, according to an embodiment.

In detail, in FIG. 12, the X axis represents a wavelength of a primary laser beam (24 of FIG. 5) and a secondary laser beam (28 of FIG. 8) each described above, and the Y axis may represent an absorbance of a base layer (12 of FIG. 8). A unit of an absorbance in the Y axis may be expressed as a percentage (%).

As described above, in the base layer 12 of a wafer temporary adhesive tape (16 of FIG. 5 and FIG. 8), an absorbance of the primary laser beam (24 of FIG. 5) may differ from that of the secondary laser beam (28 of FIG. 8) with respect to a wavelength.

As illustrated in FIG. 12, as described above, the primary laser beam (24 of FIG. 5) may have a wavelength of more than about 350 nm and less than or equal to about 650 nm. An absorbance of the base layer (12 of FIG. 8) may be low under a condition where a wavelength of the primary laser beam 24 is more than about 350 nm and less than or equal to about 650 nm. In some embodiments, less than 15% of the primary laser beam (24 of FIG. 5) may be absorbed by by the base layer (12 of FIG. 8) under a condition where a wavelength of the primary laser beam 24 is more than about 350 nm and less than or equal to about 650 nm.

As illustrated in FIG. 12, as described above, the secondary laser beam (28 of FIG. 8) may have a wavelength of about 200 nm to about 350 nm. An absorbance of the base layer (12 of FIG. 8) may be high under a condition where a wavelength of the secondary laser beam (28 of FIG. 8) is more than or equal to 200 nm and less than or equal to 350 nm. In some embodiments, 15% or more of the secondary laser beam (28 of FIG. 8) may be absorbed by the base layer (12 of FIG. 8) under a condition where a wavelength of the secondary laser beam (28 of FIG. 8) is more than 200 nm and less than or equal to 350. About 100% of the secondary laser beam (28 of FIG. 8) may be absorbed by the base layer (12 of FIG. 8) under a condition where a wavelength thereof is about 300 nm.

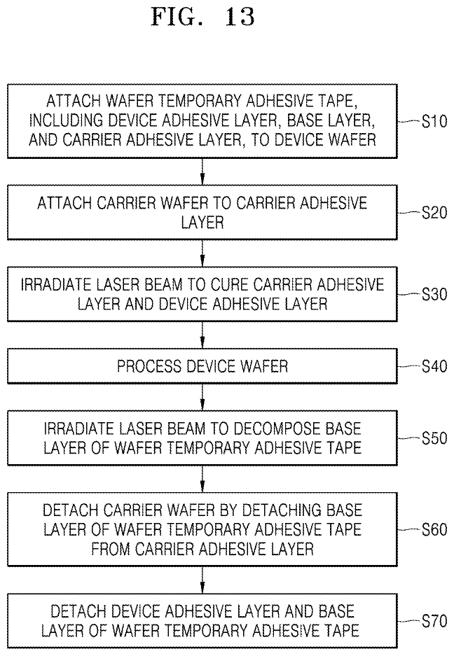

FIG. 13 is a flowchart for describing an embodiment of a method of processing a semiconductor wafer by using a wafer temporary adhesive tapet.

In detail, a cross-sectional view of a method of forming a wafer stack structure has been described above with reference to FIGS. 3 to 6. A cross-sectional view of a method of processing a wafer by using the wafer stack structure has been described above with reference to FIGS. 7 to 11.

Hereinafter, an overall method of processing a semiconductor wafer by using a wafer temporary adhesive tape will be described. In FIG. 13, the descriptions of FIGS. 3 to 11 will be briefly given or may not be repeated. In FIG. 13, the same reference numerals as those of FIGS. 3 to 11 refer to like elements.

In operation S10, the wafer temporary adhesive tape 16 including the device adhesive layer 10, the base layer 12, and the carrier adhesive layer 14 may be attached to the device wafer 18 to obtain the structure as illustrated in FIG. 3. The wafer temporary adhesive tape 16 including the device adhesive layer 10, the base layer 12, and the carrier adhesive layer 14 may be bonded to the device wafer 18. In operation S20, the carrier wafer 20 may be attached to the carrier adhesive layer 14 to obtain the structure illustrated in FIG. 4. The carrier wafer 20 may be bonded to the carrier adhesive layer 14.

In operation S30, the carrier adhesive layer 14 and the device adhesive layer 10 may be cured by irradiating the layers with a primary laser beam as illustrated in FIG. 5. The primary laser beam 24 may pass through the device adhesive layer 10, the base layer 12, and the carrier adhesive layer 14 to cure the carrier adhesive layer 14 and the device adhesive layer 10. As described above, the primary laser beam 24 may have a wavelength that allows the photo initiator 26 included in the device adhesive layer 10 and the carrier adhesive layer 14 to induce photo-curing. In some embodiments, the primary laser beam 24 may have a wavelength of more than about 350 nm less than or equal to 650 nm.

In operation S40, a process of processing the device wafer 18 may be performed to obtain the structure shown in FIG. 7. For example, the process of processing the device wafer 18 may be a process that polishes the rear surface 18b of the device wafer 18 and reduces a thickness of the device wafer 18.

In operation S50, the base layer 12 of the wafer temporary adhesive tape 16 may be decomposed by applying the secondary laser beam 28 as illustrated in FIG. 8. The secondary laser beam 28 may be applied to the interface 30 between the base layer 12 and the carrier adhesive layer 14 to chemically decompose a surface of the base layer 12.

In operation S60, the carrier wafer 20 may be detached by detaching the base layer 12 of the wafer temporary adhesive tape 16 from the carrier adhesive layer 14 as illustrated in FIG. 11. The carrier adhesive layer 14 and the carrier wafer 20 may be chemically detached (de-bonded) from the device wafer 18′.

In operation S70, the device adhesive layer 10 and the base layer 12 of the wafer temporary adhesive tape 16 may be detached. The device adhesive layer 10 and the base layer 12 may be physically detached (de-bonded) from the device wafer 18′. Through such a process, the device adhesive layer 10 and the base layer 12 may be removed from the device wafer 18′.

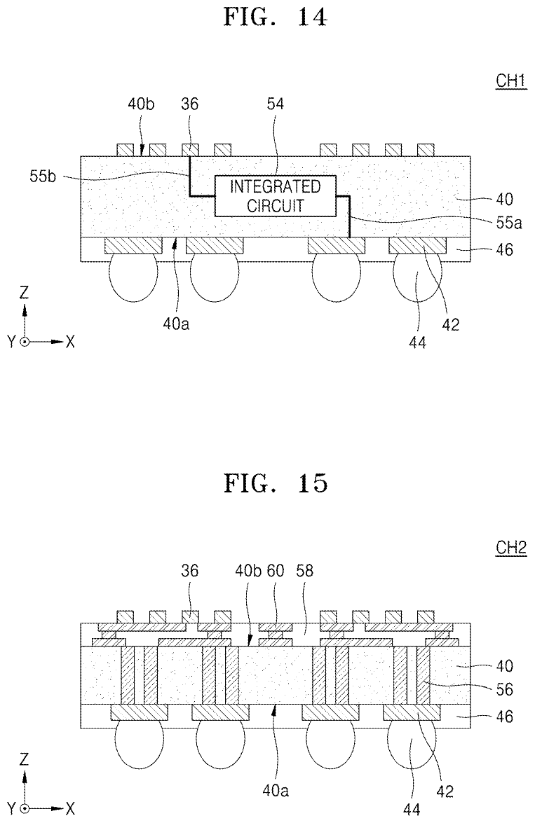

FIG. 14 is a cross-sectional view for describing a semiconductor chip manufactured by a method of processing a semiconductor wafer according to an embodiment.

In detail, a semiconductor chip CH1 may be manufactured using the device wafer 18′ illustrated in FIG. 2B. The semiconductor chip CH1 may include a device wafer 40 corresponding to the device wafer 18′ of FIG. 2B.

The semiconductor chip CH1 may include a logic chip or a memory chip including an integrated circuit 54. The integrated circuit 54 may be electrically connected with first wiring pads 42 and solder bumps 44 formed on a first surface 40a of the device wafer 40 by using a first wiring layer 55a.

A passivation layer 46 may be formed between the first wiring pads 42 on the first surface 40a of the device wafer 40. The integrated circuit 54 may be electrically connected with second wiring pads 36 formed on a second surface 40b of the device wafer 40 by using a second wiring layer 55b.

In an embodiment, the integrated circuit 54 may be electrically connected with the first wiring pads 42 and the second wiring pads 36 by using the first wiring layer 55a and the second wiring layer 55b, or the integrated circuit 54 may be electrically connected with the first wiring pads 42 and the second wiring pads 36 by using a through silicon via structure.

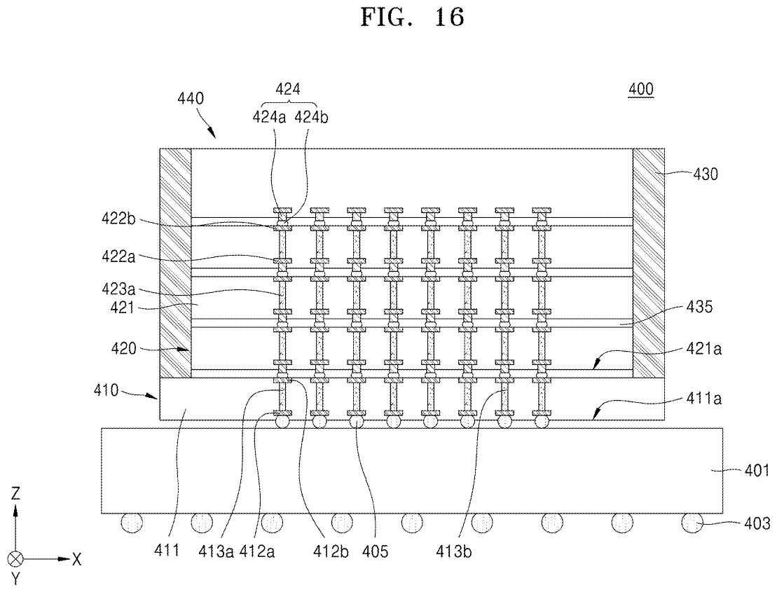

FIG. 15 is a cross-sectional view for describing a semiconductor chip manufactured by a method of processing a semiconductor wafer, according to an embodiment.

In detail, a semiconductor chip CH2 may be manufactured using the device wafer 18′ of FIG. 2B. The semiconductor chip CH2 may include a device wafer 40 corresponding to the device wafer 18′ of FIG. 2B.

The semiconductor chip CH2 may be an interposer chip including a through via structure 56 (for example, a through silicon via structure). The through via structure 56 may be electrically connected with first wiring pads 42 and solder bumps 44, which are formed on a first surface 40a of the device wafer 40. A passivation layer 46 may be formed between the first wiring pads 42 on the first surface 40a of the device wafer 40.

The through via structure 56 may be electrically connected with second wiring pads 36 formed on a second surface 40b of the device wafer 40 by using a multi-layer wiring layer 60. The multi-layer wiring layer 60 may be formed in an interlayer insulation layer 58 on the second surface 40b of the device wafer 40.

FIG. 16 is a cross-sectional view illustrating a semiconductor package 400 including a semiconductor chip manufactured by a method of processing a semiconductor wafer, according to an embodiment.

In detail, the semiconductor package 400 may include a stack semiconductor chip 440 stacked on a package substrate 401. The package substrate 401 may be a printed circuit board (PCB). A solder bump 403 may be formed on a lower surface of the package substrate 401 as an external connection terminal

The stack semiconductor chip 440 may include a first semiconductor chip 410 and a plurality of second semiconductor chips 420 mounted on the first semiconductor chip 410. The second semiconductor chips 420 may be sequentially stacked on the first semiconductor chip 410 in a vertical direction (a Z direction). A width of the first semiconductor chip 410 may be greater than that of each of the second semiconductor chips 420.

In the drawing, the stack semiconductor chip 440 is illustrated as including four second semiconductor chips 420, the second semiconductor chips 420 are not limited thereto. For example, the stack semiconductor chip 440 may include two or more second semiconductor chips 420. The first semiconductor chip 410 and the second semiconductor chips 420 may include a semiconductor chip (CH1 of FIG. 14) manufactured as described herein.

The first semiconductor chip 410 may include a first pad 412a and a second pad 412b, which are on both surfaces of a first semiconductor substrate 411. The first pad 412a may be electrically connected with the second pad 412b by using a first through via structure 413a. The first pad 412a may be electrically connected with the package substrate 401 by using a solder bump 405 as an external connection terminal. The first semiconductor chip 410 may include an active surface 411a disposed at a lower portion thereof. The first pad 412a may be a top pad. The second pad 412b may be a bottom pad.

Each of the second semiconductor chips 420 may include a third pad 422a and a fourth pad 422b, which are on opposite surfaces of a second semiconductor substrate 421. The third pad 422a may be electrically connected with the fourth pad 422b by using a second through via structure 423a. The third pad 422a may electrically connect the second semiconductor chips 420 with one another using an internal connection terminal 424. The internal connection terminal 424 may include an internal connection pad 424a and an internal bump 424b.

Each of the second semiconductor chips 420 may include an active surface 421a disposed at a lower portion thereof. The third pad 422a may be a top pad. The fourth pad 422b may be a bottom pad. The second semiconductor chips 420 of the stack semiconductor chip 440 may be adhered to one another by an adhesive layer 435. The second semiconductor chips 420 may be molded by a molding layer 430, on the first semiconductor chip 410.

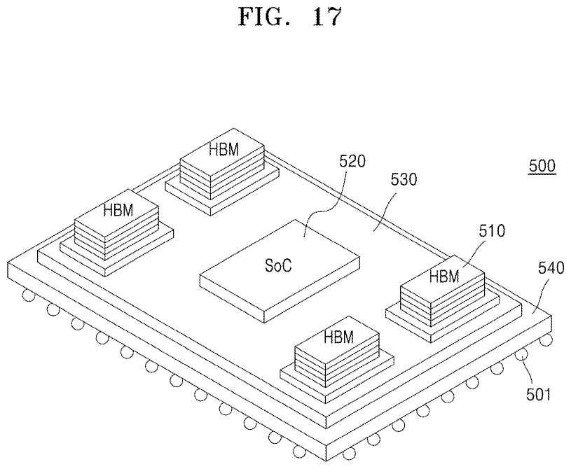

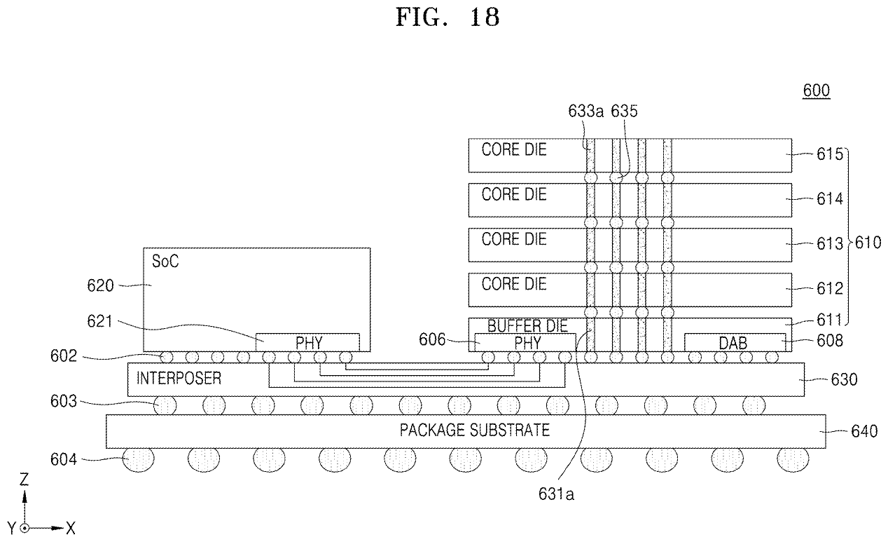

FIGS. 17 and 18 are diagrams illustrating a semiconductor package including a semiconductor chip manufactured by a method of processing a semiconductor wafer, according to an embodiment.

Referring to FIG. 17, a semiconductor package 500 may include a plurality of stack-type memory chips 510 and a system on chip 520 (SoC). The stack-type memory chips 510 and the system on chip 520 may be stacked on an interposer chip 530, and the interposer chip 530 may be stacked on the package substrate 540.

The interposer chip 530 may include a semiconductor chip (CH2 of FIG. 15) according to an embodiment. The semiconductor package 500 may transfer or receive signals to or from external other packages or electronic devices through a solder ball 501 attached on a lower portion of the package substrate 540.

Each of the stack-type memory chips 510 may be implemented based on a high bandwidth memory (HBM) standard. However, the embodiments are not limited thereto, and each of the stack-type memory chips 510 may be implemented based on a graphics digital disk recorder (GDDR) standard, hybrid memory cube (HMC) standard, or Wide I/O standard. Each of the stack-type memory chips 510 may include a semiconductor chip (CH1 of FIG. 14) according to an embodiment.

The system on chip 520 may include a plurality of memory controllers for controlling the plurality of stack-type memory chips 510 and at least one processor such as a CPU, an AP, a GPU, and a neural processing unit (NPU). The system on chip 520 may transfer or receive signals to or from a corresponding stack-type memory chip through a memory controller.

Referring to FIG. 18, a semiconductor package 600 may include a stack-type memory chip 610, a system on chip 620, an interposer chip 630, and a package substrate 640. The interposer chip 630 may include a semiconductor chip (CH2 of FIG. 15) according to an embodiment. The stack-type memory chip 610 may include a buffer die 611 and core dies 612 to 615. Each of the stack-type memory chips 610 may include a semiconductor chip (CH1 of FIG. 14) according to an embodiment.

Each of the core dies 612 to 615 may include memory cells for storing data. The buffer die 611 may include a physical layer 606 and a direct access region (DAB) 608. The physical layer 606 may be electrically connected with the physical layer 621 of the system on chip 620 through the interposer chip 630. The stack-type memory chip 610 may receive signals from the system on chip 620 through the physical layer 606, or may transfer signals to the system on chip 620.

The direct access region 608 may provide an access path that enables the stack-type memory chip 610 to be tested without using the system on chip 620. The direct access region 608 may include a conductive means (for example, a port or a pin) for directly communicating with an external test device. A test signal received through the direct access region 608 may be transferred to the core dies 612 to 615 through a plurality of through via structures. Data read from the core dies 612 to 615 so as to test the core dies 612 to 615 may be transferred to the text device through a plurality of through via structures and the direct access region 608. Accordingly, a direct access test may be performed on the core dies 612 to 615.

The buffer die 611 may be electrically connected with the core dies 612 to 615 through a plurality of through via structures 631a and 633a and a plurality of bumps 635. The buffer die 611 and the core dies 612 to 615 may include a semiconductor chip (CH1 of FIG. 14) according to embodiments.

For example, the buffer die 611 may include a first through via structure 631a. Each of the core dies 612 to 615 may include a second through via structure 633a. The buffer die 611 may receive signals, provided to each channel through the bumps 602 allocated by channel units, from the system on chip 620, or may transfer signals to the system on chip 620 through the bumps 602. For example, the bumps 602 may be micro-bumps.

The system on chip 620 may execute applications supported by the semiconductor package 600 by using the stack-type memory chip 610. The system on chip 620 may include a semiconductor chip (CH2 of FIG. 15) according to embodiments. The system on chip 620 may include at least one of a CPU, an AP, a GPU, an NPU, a tensor processing unit (TPU), a vision processing unit (VPU), an image signal processor (ISP), and a digital signal processor (DSP) and may execute specified operations. The system on chip 620 may control an overall operation of the stack-type memory chip 610. The system on chip 620 may include a physical layer 621. The physical layer 621 may include an interface circuit for transferring or receiving signals to or from the physical layer 606 of the stack-type memory chip 610. The system on chip 620 may provide various signals to the physical layer 606 through the physical layer 621. The signals provided to the physical layer 606 may be transferred to the core dies 612 to 615 through the interface circuit of the physical layer 606 and the through via structures 631a and 633a.

The interposer chip 630 may connect the stack-type memory chip 610 with the system on chip 620. The interposer chip 630 may connect the physical layer 606 of the stack-type memory chip 610 with the physical layer 621 of the system on chip 620 and may provide physical paths including conductive materials. Accordingly, the stack-type memory chip 610 and the system on chip 620 may be stacked on the interposer chip 630 and may transfer or receive signals therebetween.

The bumps 603 may be attached to an upper portion of the package substrate 640, and the solder ball 604 may be attached to a lower portion of the package substrate 640. For example, the bumps 602 may be flip-chip bumps. The interposer chip 630 may be stacked on the package substrate 640 through the bumps 603. The semiconductor package 600 may transfer or receive signals to or from external other packages or electronic devices through the solder ball 604. For example, the package substrate 640 may be a PCB.

Hereinabove, exemplary embodiments have been described in the drawings and the specification. Embodiments have been described by using the terms described herein, but this has been merely used for describing the embodiments and are not to be used for limiting a meaning or limiting the scope of embodiments defined in the following claims. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A wafer temporary adhesive tape comprising:
a device adhesive layer configured to be attached to a device wafer;
a base layer on the device adhesive layer; and
a carrier adhesive layer on the base layer, the carrier adhesive layer being configured to be attached to a carrier wafer,
wherein the base layer includes a laser decomposable material layer that is configured to be chemically decomposed by absorbing a laser beam.

2. The wafer temporary adhesive tape as claimed in claim 1, wherein the base layer includes a polymer.

3. The wafer temporary adhesive tape as claimed in claim 1, wherein the base layer includes one of polyethyleneterephthalate (PET), polyethylenenaphthalate (PEN), polyetheretherketone (PEEK), polyimide (PI), or polybenzoxazole (PBO).

4. The wafer temporary adhesive tape as claimed in claim 1, wherein the base layer absorbs the laser beam under a condition in which a wavelength of the laser beam is about 200 nm to about 350 nm.

5. The wafer temporary adhesive tape as claimed in claim 4, wherein an absorbance of the laser beam by the base layer is 15% or more under a condition in which a wavelength of the laser beam is about 200 nm to about 350 nm.

6. The wafer temporary adhesive tape as claimed in claim 1, wherein an absorbance of the laser beam by the base layer is less than 15% under a condition in which a wavelength of the laser beam is more than about 350 nm and about 650 nm or less.

7. The wafer temporary adhesive tape as claimed in claim 1, wherein a thickness of the base layer is thicker than a thickness of the device adhesive layer or the carrier adhesive layer.

8. The wafer temporary adhesive tape as claimed in claim 1, wherein each of the device adhesive layer and the carrier adhesive layer includes an acrylic polymer, a cross linker, an additive, and a photo initiator.

9. The wafer temporary adhesive tape as claimed in claim 1, wherein each of the device adhesive layer and the carrier adhesive layer includes a photo initiator for inducing photo-curing under a condition in which a wavelength of the laser beam is more than about 350 nm and about 650 nm or less.

10. A wafer stack structure comprising:
a device wafer;
a carrier wafer that is configured to support the device wafer; and
a wafer temporary adhesive tape between the device wafer and the carrier wafer, wherein
the wafer temporary adhesive tape includes:
a device adhesive layer attached on the device wafer;
a base layer on the device adhesive layer; and
a carrier adhesive layer attached to the carrier wafer, on the base layer, wherein the base layer includes a laser decomposable material layer that can be chemically decomposed by absorbing a laser beam.

11. The wafer stack structure as claimed in claim 10, wherein the carrier wafer includes a glass material or a transparent acryl material, and the device wafer includes a semiconductor material.

12. The wafer stack structure as claimed in claim 10, wherein the base layer includes one of polyethyleneterephthalate (PET), polyethylenenaphthalate (PEN), polyetheretherketone (PEEK), polyimide (PI), or polybenzoxazole (PBO).

13. The wafer stack structure as claimed in claim 10, wherein the base layer absorbs the laser beam under a condition in which a wavelength of the laser beam is about 200 nm to about 350 nm, and an absorbance of the laser beam by the base layer is 15% or more.

14. The wafer stack structure as claimed in claim 10, wherein an absorbance of the laser beam by the base layer is less than 15% under a condition in which a wavelength of the laser beam is more than about 350 nm and about 650 nm or less.

15. The wafer stack structure as claimed in claim 10, wherein each of the device adhesive layer and the carrier adhesive layer includes an acrylic polymer, a cross linker, an additive, and a photo initiator, and the photo initiator includes a material for inducing photo-curing under a condition in which a wavelength of the laser beam is more than about 350 nm and about 650 nm or less.

16. A method of processing a semiconductor wafer, the method comprising:
attaching a wafer temporary adhesive tape, including a device adhesive layer, a base layer, and a carrier adhesive layer, to a device wafer;
attaching a carrier wafer to the carrier adhesive layer;
primarily irradiating a laser beam to cure the carrier adhesive layer and the device adhesive layer;
processing the device wafer;
secondarily irradiating a laser beam to chemically decompose the base layer;
detaching the base layer from the carrier adhesive layer to detach the carrier wafer from the device wafer; and
detaching the device adhesive layer and the base layer from the device wafer.

17. The method as claimed in claim 16, wherein the base layer includes a laser decomposable material layer that is configured to be decomposed by absorbing the secondarily irradiated laser beam, and
the secondarily irradiated laser beam is applied to an interface between the base layer and the carrier adhesive layer to chemically decompose the base layer.

18. The method as claimed in claim 16, wherein, when a wavelength of the secondarily irradiated laser beam is about 200 nm to about 350 nm, the base layer absorbs the secondarily irradiated laser beam, and an absorbance of the secondarily irradiated laser beam of the base layer is 15% or more.

19. The method as claimed in claim 16, wherein, when a wavelength of the primarily irradiated laser beam is more than about 350 nm and equal to or less than 650 nm, and an absorbance of the primarily irradiated laser beam of the base layer is less than 15%.

20. The method as claimed in claim 16, wherein each of the device adhesive layer and the carrier adhesive layer includes an acrylic polymer, a cross linker, an additive, and a photo initiator, and the photo initiator includes a material for inducing photo-curing under a condition where a wavelength of the laser beam is more than about 350 nm and equal to or less than 650 nm.
